(19) United States
(12) Patent Application Publication
(10) Pub. No.: US 2024/0203699 A1
(43) Pub. Date: Jun. 20, 2024

(54) SUBSTRATE TREATMENT METHOD AND SUBSTRATE TREATMENT SYSTEM

(71) Applicant: SEMES CO., LTD., Cheonan-si (KR)

(72) Inventors: Young Jo JIN, Hwasung-si (KR); Dong Young JANG, Seongnam-si (KR); Yun Sang KIM, Seongnam-si (KR); Min Sung JEON, Osan-si (KR); Min Hee HONG, Suwon-si (KR); Young Seo PARK, Hwaseong-si (KR); Jeong Sik KIM, Bucheon-si (KR)

(73) Assignee: SEMES CO., LTD., Cheonan-si (KR)

(21) Appl. No.: 18/538,919

(22) Filed: Dec. 13, 2023

(30) Foreign Application Priority Data
Dec. 14, 2022 (KR) 10-2022-0174983

(51) Int. Cl. H01J 37/32; H01L 21/02; H01L 21/67

(52) U.S. Cl. CPC H01J 37/32449; H01J 37/32201; H01L 21/02274; H01L 21/67098; H01L 21/67248

(57) ABSTRACT

Proposed are a substrate treatment method and a substrate treatment system in which a cooling process with an improved cooling speed and an improved cooling efficiency is applied in a substrate treatment process using an upper heat source. A substrate treatment method etching a substrate at an atomic layer level by using a processing unit and a thermal treatment unit may be provided. The substrate treatment method includes a surface treatment process in which a substrate surface is modified in the processing unit, a desorption process in which the substrate surface-treated in the processing unit is heated by the upper heat source in the thermal treatment unit, thereby generating a desorption reaction on the substrate surface, and a temperature adjustment process in which the substrate is cooled by a cooling plate in the thermal treatment unit, thereby maintaining a temperature of the substrate at a set temperature range.

### CROSS REFERENCE TO RELATED APPLICATION

The present application claims priority to Korean Patent Application No. 10-2022-0174983, filed on Dec. 14, 2022, the entire contents of which is herein incorporated by reference.

### BACKGROUND OF THE INVENTION

### 1. Field of the Invention

The present disclosure relates to a substrate treatment system and a substrate treatment method in which a heat source for heating a treatment target is provided above the treatment target.

### 2. Description of the Related Art

In order to manufacture a semiconductor device, a desired pattern is formed on a substrate by performing various processes such as a photolithography process, an etching process, an ashing process, an ion implantation process, a thin film deposition process, a cleaning process, and so on. Among the various processes, the etching process is a process of removing a selected heating region in a film formed on the substrate, and a wet etching process and a dry etching process are used.

For the dry etching process, an etching apparatus using plasma is used. Generally, in order to form the plasma, an electromagnetic field is generated in an inner space of a chamber, and the electromagnetic field excites a process gas provided in the chamber into a plasma state.

Plasma refers to an ionized gaseous state composed of ions or electrons, radicals, and so on. Plasma may be generated by a very high temperature, a strong electric field, or an RF electromagnetic field. In a semiconductor device manufacturing process, the etching process may be performed using plasma.

In some plasma processes, a thermal treatment apparatus in which a heat source is disposed above the substrate is used so as to thermally treat the substrate. An upper heat source may heat the substrate at a faster speed than a lower heat source. Generally, a thermal treatment apparatus that uses the upper heat source maintains a temperature of the substrate by cooling the substrate in an air-cooling method. Although the air-cooling method has an advantage of cooling the substrate with a simple structure, cooling speed is slow and cooling efficiency is low, so there is a difficulty in maintaining a temperature of the substrate constant in response to a rapid increase in the substrate temperature. For example, in an Atomic Layer Deposition (ALD) process or an Atomic Layer Etching (ALE) process in which heating and cooling of the substrate is repeated, a cooling speed in the cooling of the substrate using the air-cooling method is so slow compared to a heating speed of the substrate, so that the temperature of the substrate and the temperature of the treatment space may increase as the process is repeated. Accordingly, the same process conditions may not be maintained consistently, so that the process recipe may become unstable. In addition, there is a possibility that a thin film or a pattern on the substrate may be damaged as the substrate is overheated due to an increase in temperature of the substrate. In addition, overheating of the substrate may change the physical properties of the thin film or may cause an overetching of the thin film. An increase in temperature of the treatment space may reduce an etching rate by reducing a reactivity of a precursor.

### SUMMARY OF THE INVENTION

Accordingly, the present disclosure has been made keeping in mind the above problems occurring in the related art, and an objective of the present disclosure is to provide a substrate treatment method and a substrate treatment system that are capable of rapidly cooling a substrate in a thermal treatment process using an upper heat source.

In addition, another objective of the present disclosure is to provide a substrate treatment method and a substrate treatment system that are capable of maintaining a constant process temperature and a constant temperature of the substrate even in a repetitive process.

In addition, still another objective of the present disclosure is to provide a substrate treatment method and a substrate treatment system that are capable of preventing damage to a substrate and deformation of the substrate due to overheating of the substrate.

The problems to be solved by the inventive concept are not limited to the above-mentioned problems, and the problems not mentioned will be clearly understood by those of ordinary skill in the art to which the inventive concept belongs from the present specification and the accompanying drawings.

According to an embodiment of the present disclosure, a substrate treatment method etching a substrate at an atomic layer level by using a processing unit and a thermal treatment unit may be provided. The substrate treatment method includes: a surface treatment process in which a surface of the substrate is modified in the processing unit; a desorption process in which the substrate that is surface-treated in the processing unit is heated by an upper heat source in the thermal treatment unit, thereby generating a desorption reaction on the surface of the substrate that is surface-treated; and a temperature adjustment process in which the substrate is cooled by a cooling plate in the thermal treatment unit, thereby maintaining a temperature of the substrate at a set temperature range.

According to an embodiment of the present disclosure, there is provided a substrate treatment system including: a processing unit configured to treat a surface of a substrate by using plasma; and a thermal treatment unit configured to etch the substrate at an atomic layer level by heating the substrate that is surface-treated in the processing unit. The thermal treatment unit may include: a chamber having a thermal treatment space therein; a heating unit including an upper heat source and being configured to heat the substrate; and a cooling plate configured to cool the substrate in a contact method in the thermal treatment space, and a cooling flow path in which a cooling fluid flows may be provided inside the cooling plate.

According to an embodiment of the present disclosure, there is provided a substrate treatment method etching a substrate including a ruthenium (Ru) thin film at an atomic layer level by using a processing unit and a thermal treatment unit. The substrate treatment method includes: a surface treatment process in which a surface of the thin film is modified in the processing unit; a first substrate transfer process in which the substrate that is surface-treated in the surface treatment process is transferred to the thermal treatment unit from the processing unit; a desorption process in which the substrate that is transferred to the thermal treatment unit and surface-treated is heated by an upper heat source, thereby generating a desorption reaction on the surface of the substrate that is surface-treated so that the substrate is etched at an atomic layer level; and a temperature adjustment process in which the substrate is cooled by a cooling plate in the thermal treatment unit, thereby maintaining a temperature of the substrate at a set temperature range, wherein the surface treatment process, the desorption process, and the temperature adjustment process constitute one cycle and are repeated one or more times, and the substrate treatment method includes a second substrate transfer process of transferring the substrate in which the temperature adjustment process is completed to the processing unit from the thermal treatment unit when a subsequent cycle exists.

According to an embodiment of the present disclosure, by using the contact method, the cooling speed and the cooling efficiency may be increased, so that the temperature increase phenomenon of the entire substrate and the treatment space due to the repeated processes may be prevented. Accordingly, since the temperature of the entire substrate and the treatment space may be maintained in a predetermined range, the substrate may be treated under the same process condition even in the repeated processes. That is, process stability and process reproducibility may be secured.

In addition, since overheating of the substrate is prevented, deformation of the substrate and damage to the substrate (for example: damage to a pattern, damage to a surface of a thin film, and so on) due to overheating of the substrate may be prevented. In addition, changes in the physical properties of the thin film that may occur as the temperature of the substrate exceeds an allowable range may be prevented, and the generation of the harmful gas may be prevented.

In addition, the process time may be shortened by high-speed heating and high-speed cooling, and the temperature of the substrate may be maintained at the set temperature range by cooling the lower surface of the substrate while the heating process is performed. Particularly, when the concentrated thermal treatment on the surface of the substrate is performed, damage to the lower portion of the substrate may be prevented at the same time.

In addition, by a dual chamber configuration, since the temperature range of the surface treatment process and the temperature range of the desorption process do not affect each other, the process temperature range may be expanded and the etch selectivity may be increased.

The effects of the inventive concept are not limited to the above-mentioned effects, and the other unmentioned effects will become apparent to those skilled in the art from the following description and drawings.

### BRIEF DESCRIPTION OF THE DRAWINGS

The above and other objectives, features, and other advantages of the present disclosure will be more clearly understood from the following detailed description when taken in conjunction with the accompanying drawings, in which:

FIG. 1 is a plan view illustrating a substrate treatment system according to an embodiment of the present disclosure;

FIG. 2 is a cross-sectional view illustrating a processing unit and a thermal treatment unit in FIG. 1;

FIG. 3 is a cross-sectional view illustrating the processing unit in FIG. 2;

FIG. 4 and FIG. 5 are cross-sectional views illustrating the thermal treatment unit in FIG. 2;

FIG. 6 is an enlarged perspective view illustrating a cooling plate according to an embodiment of the present disclosure;

FIG. 7 is a flowchart illustrating a substrate treatment method according to an embodiment of the present disclosure;

FIG. 8 is a view illustrating an example in which the substrate treatment method in FIG. 7 is applied; and

FIGS. 9A and 9B are view illustrating experimental data comparing an example of applying the present disclosure to a conventional technology to the substrate illustrated in FIG. 8.

### DETAILED DESCRIPTION OF THE INVENTION

Hereinafter, exemplary embodiments of the present disclosure will be described in detail with reference to the accompanying drawings so that those skilled in the art can easily implement the present disclosure. The present disclosure is not limited to the exemplary embodiments described herein and may be embodied in many different forms.

In order to clearly describe the present disclosure, parts irrelevant to the description are omitted, and the same reference numerals designate the same or similar components throughout the specification.

In addition, in various exemplary embodiments, components having the same configuration will be described only in representative exemplary embodiments by using the same reference numerals, and in other exemplary embodiments, only configurations different from the representative exemplary embodiments will be described.

Throughout the specification, when a part is said to be “connected (or coupled)” to another part, an expression such as “connected (or coupled)” is intended to include not only “directly connected (or coupled)” but also “indirectly connected (or coupled)” having a different member interposed therebetween. In addition, it will be further understood that when a part “comprises”, “includes”, or “has” an element, this means that other elements are not excluded but may be further included, unless otherwise stated.

Unless defined otherwise, all terms used herein including technical or scientific terms have the same meanings as generally understood by a person having ordinary knowledge in the art to which the present disclosure pertains. The terms defined in general dictionaries are construed as having meanings consistent with the contextual meanings of the art, but not interpreted as ideal meanings or excessively formal meanings unless explicitly defined in the present application.

A substrate according to an embodiment of the present disclosure may be a silicon substrate based on a semiconductor wafer. At this time, the substrate may include a thin film formed on an upper portion of the substrate, and the thin film formed on the upper portion of the substrate may be a ruthenium (Ru) thin film.

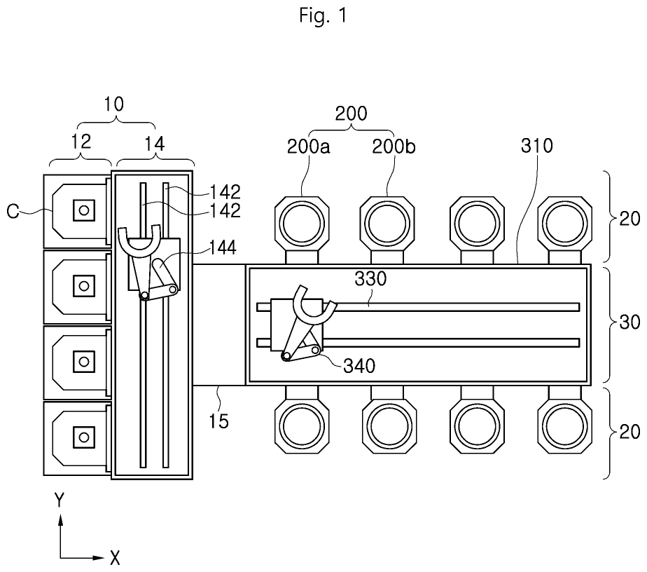

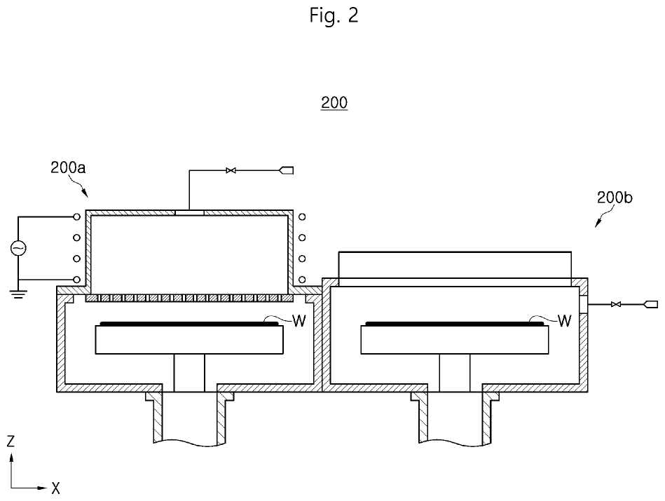

FIG. 1 is a plan view illustrating a substrate treatment system according to an embodiment of the present disclosure, and FIG. 2 is a cross-sectional view schematically illustrating a processing unit and a thermal treatment unit in FIG. 1.

Referring to FIG. 1 and FIG. 2, a semiconductor manufacturing facility may include an index module 10, a treatment module 20, and a substrate transfer module 30 configured to transfer a substrate between the index module 10 and the treatment module 20. According to an embodiment of the present disclosure, the index module 10 and the treatment module 20 may be sequentially arranged in a row.

The index module 10 may include a load port 12 where a carrier C in which the substrate is stored is seated, and may include an index frame 14 configured to pull out a substrate W from the carrier C seated in the load port 12 or to bring a substrate in which a process treatment is finished into the carrier C. The load port 12 is positioned on an opposite side of the treatment module 20 with respect to the index frame 14. The carrier C is disposed on the load port 12 and may be provided with a plurality of carriers C, and the substrates W may be stored in the carriers C.

An index robot 144 may be provided inside the index frame 14. The index robot 144 may be provided such that the index robot 144 is capable of being moved along a rail 142. The index robot 144 may receive the substrate from the carrier C, and may transfer the substrate to a load lock chamber 15 in which the substrate is temporarily stored or may transfer the substrate temporarily stored in the load lock chamber 15 to an inside of the carrier C.

The treatment module 20 may include at least one processing unit 200 in which a process treatment of the substrate is performed. As illustrated in FIG. 1, the processing unit 200 may be provided with a plurality of processing units 200. Each of the processing units 200 may perform the same process, or may perform different processes.

Referring to FIG. 2, a processing unit 200a according to an embodiment of the present disclosure may perform a surface treatment process in which a surface of the substrate is modified, and a thermal treatment unit 200b may perform a desorption process in which a desorption reaction occurs on the surface of the surface-treated substrate. By the processing unit 200a and the thermal treatment unit 200b, the surface of the substrate may be etched at an atomic layer level. The substrate W in which the surface treatment process is completed by the processing unit 200a may be transferred to the thermal treatment unit 200b, and the substrate W in which the desorption process is performed by the thermal treatment unit 200b may be transferred to the processing unit 200a again or may be transferred to the load lock chamber 15. Alternatively, the substrate W may be transferred to a processing unit 200 other than the processing unit 200a. The processing unit 200a and the thermal treatment unit 200b will be described later in detail.

Meanwhile, as illustrated in the drawings, the processing unit 200a and the thermal treatment unit 200b may be disposed adjacent to each other. However, since a position relationship between the processing unit 200a and the thermal treatment unit 200b is selectively changeable, the scope of the present disclosure is not limited thereto. As an example, the processing unit 200a and the thermal treatment unit 200b may be disposed opposite to each other or may be disposed to be spaced apart from each other on the same line. Hereinafter, for convenience of description, a treatment space of the processing unit 200a is referred to as a processing space, and a treatment space of the thermal treatment unit 200b is referred to as a thermal treatment space.

The substrate transfer module 30 may be disposed adjacent to the treatment module 20, and may receive the substrate from the load lock chamber 15 and then may transfer the substrate to the treatment module 20, or may transfer the substrate in which the process treatment is finished in the treatment module 20 to the load lock chamber 15. The substrate transfer module 30 may include a rail 330 disposed along a direction in which the processing units 200 are disposed, and may include a substrate transfer robot 340 configured to move along the rail 330 and to transfer the substrate. The substrate transfer robot 340 may return the substrate while moving in an inner space of a return chamber 310.

Meanwhile, as illustrated in FIG. 1, the treatment module 20 may be provided in an in-line type, but may be provided in a cluster type unlike the in-line type illustrated in FIG. 1.

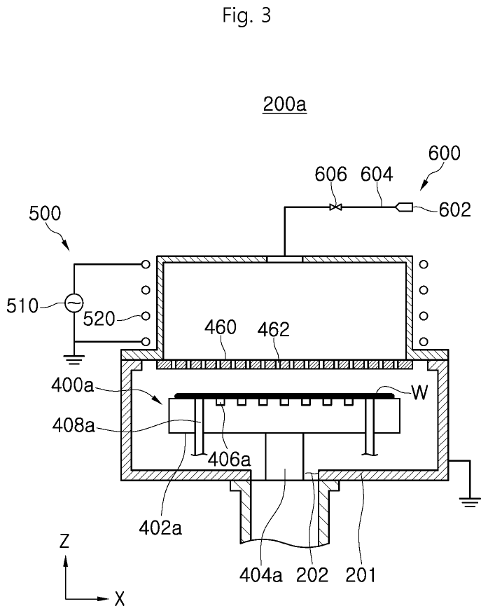

FIG. 3 is a cross-sectional view schematically illustrating a processing unit according to an embodiment of the present disclosure.

Referring to FIG. 3, the processing unit 200a may include a chamber 201, a supporting unit 400a, a plasma generation unit 500, and a gas supply unit 600.

The chamber 201 has an inner portion provided with the processing space in which the substrate W is placed and a plasma process is performed. Such a chamber may have an opening part (not illustrated) formed on a side wall of the chamber. The substrate may enter and exit inner and outer portions of the chamber through the opening part (not illustrated). The opening part (not illustrated) may be opened and closed by an opening and closing member such as a door. An exhaust hole 202 may be formed in a bottom surface of the chamber 201. The exhaust hole 202 may provide a passage through which gas and reaction by-products that remain in the processing space inside the chamber 201 are discharged to the outside.

The supporting unit 400a for supporting the substrate W is provided inside the chamber 201. The supporting unit 400a may include a supporting member 402a and a supporting shaft 404a. The supporting member 402a may be disposed in the processing space of the chamber 201, and may be provided in a circular plate shape. The supporting member 402a may be supported by the supporting shaft 404a. The substrate W may be positioned on an upper surface of the supporting member 402a, and an electrode (not illustrated) may be formed inside the supporting member 402a. The electrode (not illustrated) may be connected to an external power source (not illustrated), and may generate static electricity by the applied power. The generated static electricity may fix the substrate W to the supporting member 402a. Alternatively, a plurality of vacuum holes (not illustrated) for vacuum-adsorbing the substrate W may be formed in the upper surface of the supporting member 402a. The vacuum holes (not illustrated) may be connected to a vacuum pump (not illustrated), and a pressure of each vacuum hole may be reduced to a predetermined pressure by the vacuum pump (not illustrate), thereby being capable of adsorbing the substrate W.

A cooling member 406a may be provided inside the supporting member 402a. The cooling member 406a may be provided as a cooling line in which a cooling fluid flows. As an example, the cooling fluid may be one of a cooling gas (for example: nitrogen), a process cooling water, or a coolant. The cooling member 406a may maintain a temperature of the substrate W in a predetermined range by cooling the substrate W. The substrate W in which a process is completed may be cooled to a temperature required for a next process or may be cooled to a room temperature by the cooling member 406a. In addition, the cooling member 406a may prevent the substrate W from overheating by cooling the substrate W while the process is performed. Meanwhile, in the drawings, it is illustrated that the cooling member 406a exists on a surface of the supporting member 402a for emphasis, but the cooling member 406a may be provided in a state in which the cooling member 406a is embedded in an upper region of the supporting member 402a.

Selectively, the supporting unit 400a may further include a lift driving part. The lift driving part may include a plurality of lifting pins 408a supporting a lower surface of the substrate W, and the plurality of lifting pins 408a may be accommodated in a plurality of pin holes that penetrates the supporting member 402a in up and down directions. The plurality of lifting pins 408a may be moved upward while being in a state in which the plurality of lifting pins 408a is in contact with the lower surface of the substrate W and is supporting the substrate W. As an example, the lift driving part may be provided with three lifting pins 408a supporting different regions, so that the substrate W may be moved upward or downward from the supporting member 402a. Upward and downward lift driving of each lifting pin 408a may be individually or integrally performed, and the upward and downward lift driving of the lifting pins 408a may be performed by a driving apparatus such as a linear motor, a cylinder, a ball screw, and so on. Meanwhile, although not illustrated in detail, the lifting pin 408a may be provided such that the lifting pin 408a is capable of adsorbing the substrate W by a vacuum method or an electrostatic method so that a position of the substrate W is capable of being fixed even during a lifting process. The number of the lifting pins 408a may be increased or decreased as required.

The plasma generation unit 500 may generate plasma in the processing space. The plasma generated by the plasma generation unit 500 may be formed in an upper region of the supporting unit 400a. As illustrated in the drawings, the plasma generation unit 500 may be provided in a form in which plasma is generated in the processing space by using an Inductively Coupled Plasma (ICP) source. However, since a form in which plasma is generated in the processing space is capable of being changed in design, the scope of the present disclosure is not limited thereto. As an example, the plasma generation unit 500 may generate plasma in the processing space inside the chamber 201 by using a Capacitively Coupled Plasma (CCP) source or a microwave.

The plasma generation unit 500 may include an upper power source 510 and an antenna unit 520. The upper power source 510 may apply power to the antenna unit 520. The upper power source 510 may be provided such that characteristics of plasma are capable of being controlled. For example, the upper power source 510 may be configured to adjust plasma density.

The antenna unit 520 may be mounted on an upper side wall of the chamber 201. The antenna unit 520 may include a coil provided such that the coil forms a closed loop. The antenna unit 520 may perform a function that excites a process gas introduced inside the chamber 201 into plasma on the basis of the power supplied from the upper power source 510.

A shower head 460 may be formed such that the shower head 460 vertically faces the supporting member 402a from inside the chamber 201. The shower head 460 may be provided with a plurality of gas injection holes 462 for evenly injecting gas into the chamber 201, and may be provided such that the shower head 460 has a diameter larger than a diameter of the supporting member 402a. The shower head 460 may be manufactured of a silicone material, and may be manufactured of a material having a metal component.

The gas supply unit 600 may supply gas required for the process to the chamber 201. Specifically, the gas supply unit 600 may supply a process gas including oxygen, a precursor, or a purge gas to the processing space of the processing unit 200a. The gas supply unit 600 may include a gas supply source 602, a gas supply line 604, and a gas injection nozzle. The gas supply line 604 may connect the gas supply source 602 and the gas injection nozzle to each other. A gas supply valve 606 configured to open or close a passage of the gas supply line 604 or configured to adjust a flow rate of fluid flowing along the passage may be mounted on the gas supply line 604.

Although only one gas supply source 602 and one gas supply valve 606 are illustrated in FIG. 3, the gas supply source 602 may include a plurality of gas supply sources and a plurality of gas supply valves capable of independently controlling the supply of each gas. At this time, the plurality of gases may include a process gas used in a substrate treatment process, a precursor, an inert gas for purging, and so on.

According to the configuration described above, in the processing unit 200a, an oxide film may be formed on the surface of the substrate through a plasma treatment of the substrate, and a ligand of the surface of the substrate may be exchanged by injecting a precursor. As an example, the processing unit 200a may generate plasma including oxygen, thereby being capable of forming the oxide film on the surface of the substrate. After then, the ligand of the oxidized surface of the substrate may be exchanged by supplying a precursor to the processing space. Between the plasma treatment process and the precursor supply process, a purge treatment process in which the processing space is purged may be performed.

As an example, since a ruthenium (Ru) oxide film on the substrate may be oxidized by the plasma treatment, a ruthenium oxide (RuO₂) film may be formed on the surface. In ruthenium, when the temperature of the substrate is overheated to a temperature of equal to or more than 100 degrees Celsius by a repeated process, an additional etching (overetching) occurs during a surface modification process, and ruthenium tetroxide (RuO₄) that is volatile may be formed other than ruthenium dioxide (RuO₂) that is non-volatile. Since ruthenium tetroxide (RuO₄) in a gaseous state is a toxic gas and may cause environmental safety problems, maintaining a temperature of the substrate in a ruthenium etching process is significantly important.

However, cooling of a substrate by using a conventional air-cooling method has a very slow cooling speed and has a low cooling efficiency. Therefore, since the temperature of the heated substrate is not effectively lowered, the temperature of the substrate may gradually increase when the repeated process is performed. That is, in a treatment process that requires a repeated process such as an Atomic Layer Deposition (ALD) process and an Atomic Layer Etching (ALE) process, the temperature of the substrate is not maintained consistently, so that process conditions and process recipes become unstable. Unstable process conditions and unstable process recipes have difficulties in securing process reproducibility and quality reliability. In the present disclosure, a method capable of stably maintaining the temperature of the substrate by cooling the substrate in a contact method and increasing the cooling speed and the cooling efficiency of the substrate is proposed.

When the surface treatment process of the substrate W is completed in the processing unit 200a, the substrate W may be transferred to the thermal treatment unit 200b by the substrate transfer robot 340 of the substrate transfer module 30. In the substrate W transferred to the thermal treatment unit 200b, a desorption reaction may occur on the surface of the substrate W by a heating treatment. While the substrate W is moved from the processing unit 200a to the thermal treatment unit 200b, the substrate transfer module 30 may maintain a vacuum state.

Until the substrate W is etched to a target thickness, the substrate W may be repeatedly transferred alternately between the processing unit 200a and the thermal treatment unit 200b. For example, the substrate W in which the process performed in the processing unit 200a is completed is transferred to the thermal treatment unit 200b, the substrate W in which the process performed in the thermal treatment unit 200b is completed is transferred to the processing unit 200a again, and this process may be repeatedly performed until etching on the substrate W is performed to the target thickness.

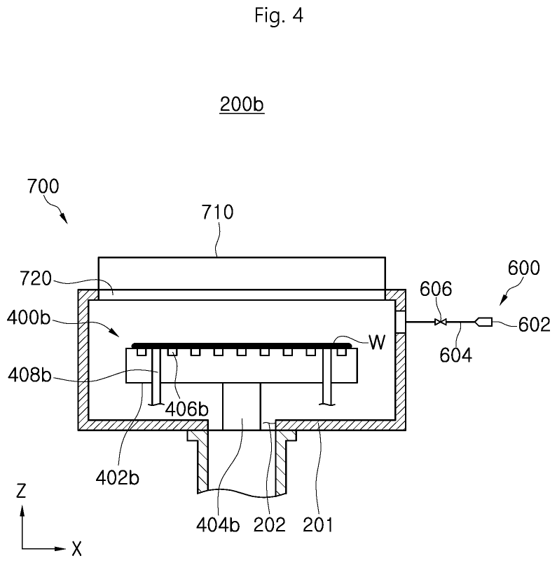

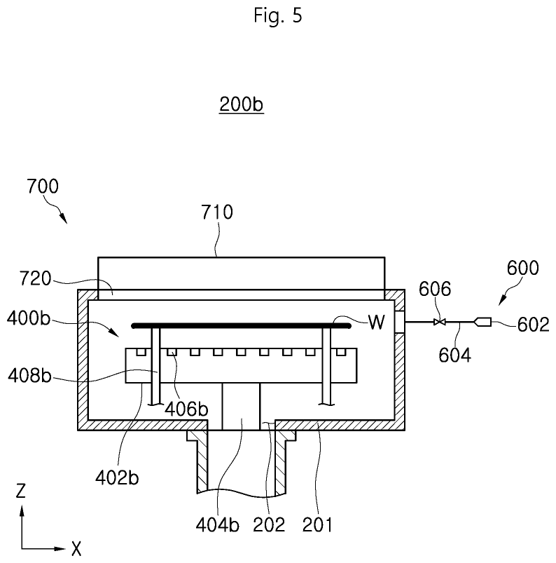

FIG. 4 and FIG. 5 are views schematically illustrating the thermal treatment unit according to an embodiment of the present disclosure. The thermal treatment unit 200b may perform a desorption process in which a desorption reaction occurs on the surface of the surface-treated substrate W by using inert gas and heat without using plasma.

Referring to FIG. 4 and FIG. 5, unlike the processing unit 200a in FIG. 3, the thermal treatment unit 200b does not use plasma, and performs the desorption process by using a heating unit 700.

The thermal treatment unit 200b may include the chamber 201, a cooling plate 400b, the gas supply unit 600, and the heating unit 700.

The chamber 201 has the inner portion provided with the processing space in which the substrate W is placed and the plasma process is performed. Such a chamber may have an opening part (not illustrated) formed on a side wall of the chamber. The substrate may enter and exit inner and outer portions of the chamber through the opening part (not illustrated). The opening part (not illustrated) may be opened and closed by an opening and closing member such as a door. The exhaust hole 202 may be formed in the bottom surface of the chamber 201. The exhaust hole 202 may provide the passage through which gas and reaction by-products that remain in the thermal treatment space inside the chamber 201 are discharged to the outside.

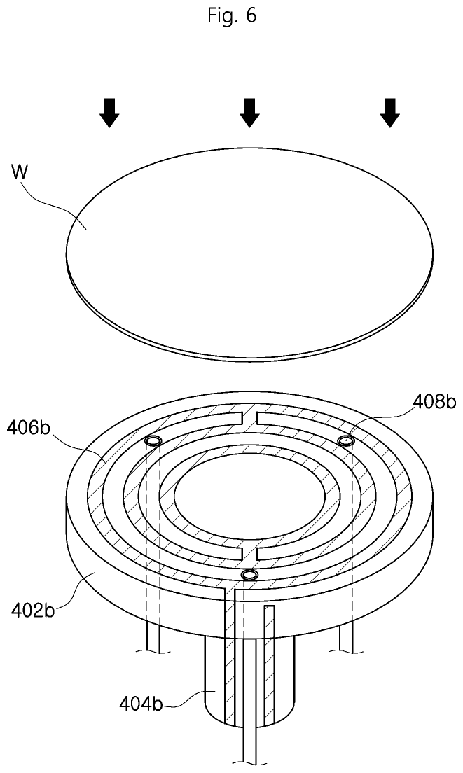

The cooling plate 400b for cooling the substrate W is provided inside the chamber 201. The cooling plate 400b is configured to cool the substrate W seated on an upper surface of the cooling plate 400b. FIG. 6 is a view illustrating an example of the cooling plate 400b. The cooling plate 400b cools the substrate W while supporting the lower surface of the substrate W. The cooling plate 400b may include a supporting member 402b and a supporting shaft 404b. The supporting member 402b may be disposed in the thermal treatment space of the chamber 201, and may be provided in a circular plate shape. The supporting member 402b may be supported by the supporting shaft 404b. The substrate W may be placed on an upper surface of the supporting member 402b.

Referring to FIG. 6, a cooling member 406b may be provided inside the supporting member 402b. The cooling member 406b may be provided as a cooling flow path through which a cooling fluid flows. As an example, the cooling fluid may be one of a cooling gas (for example: nitrogen), a process cooling water, or a coolant. The cooling member 406b may maintain a temperature of the substrate W in a predetermined range by cooling the substrate W. Meanwhile, a shape of the cooling flow path may be changed as required. Meanwhile, in the drawings, it is illustrated that the cooling member 406b exists on a surface of the supporting member 402b for emphasis, but the cooling member 406b may be provided in a state in which the cooling member 406b is embedded in an upper region of the supporting member 402b.

The cooling member 406b cools the substrate W by a contact method rather than an air-cooling method. Accordingly, the cooling speed and the cooling efficiency of the substrate W may be increased compared to the conventional cooling method. The cooling member 406b may cool the substrate W in which the process has been completed to room temperature or to a temperature required for the next process. In addition, the cooling member 406b may prevent the substrate W from overheating by cooling the substrate W while the thermal treatment process is performed. Particularly, due to a lower portion of the substrate W being cooled by the cooling member 406b during a rapid thermal treatment process, a thermal energy applied to the upper surface of the substrate W is minimized to reach the lower surface of the substrate W, so that the thermal treatment may be concentrated on the surface of the substrate W. As described above, since the cooling unit 400 prevents overheating of the substrate W, deformation and damage (including damage to the lower portion of the substrate W) of the substrate W caused by overheating of the substrate W may be prevented and changes in physical properties of the thin film and so on may be prevented. As an example, the cooling member 406b may maintain the temperature of the substrate W at a temperature below 100 degrees Celsius so as to prevent the generation of ruthenium tetroxide that is a harmful gas on the ruthenium thin film, rather than ruthenium dioxide that is non-volatile.

The cooling plate 400b may further include a lift driving part. The lift driving part may include a plurality of lifting pins 408b supporting the lower surface of the substrate W, and the plurality of lifting pins 408b may be accommodated in a plurality of pin holes that penetrates the supporting member 402a in up and down directions. The plurality of lifting pins 408b may be moved upward while being in a state in which the plurality of lifting pins 408b is in contact with the lower surface of the substrate W and is supporting the substrate W. For an example, as illustrated in FIG. 6, the lift driving part may be provided with three lifting pins 408b supporting different regions, so that the substrate W may be moved upward or downward from the supporting member 402b. Upward and downward lift driving of each lifting pin 408b may be individually or integrally performed, and the upward and downward lift driving of the lifting pins 408b may be performed by a driving apparatus such as a linear motor, a cylinder, a ball screw, and so on. The number of the lifting pins 408b may be increased or decreased as required.

The gas supply unit 600 may supply gas required for the process to the chamber 201. Specifically, the gas supply unit 600 may supply a purge gas to the thermal treatment space of the thermal treatment unit 200b. The gas supply unit 600 may include the gas supply source 602, the gas supply line 604, and the gas injection nozzle. The gas supply line 604 may connect the gas supply source 602 and the gas injection nozzle to each other. The gas supply valve 606 configured to open or close the passage of the gas supply line 604 or configured to adjust a flow rate of fluid flowing along the passage may be mounted on the gas supply line 604. The purge gas may be an inert gas.

In order to supply the inert gas and heat to the substrate in which the surface thereof is modified so that a desorption reaction at an atomic level occurs on the surface of the substrate, the heating unit 700 may be provided on the upper portion of the thermal treatment unit 200b. The heating unit 700 is provided with an upper heat source 710 for generating thermal energy, thereby being capable of supplying heat to the substrate W positioned at a lower side facing the upper heat source 710. According to an embodiment of the present disclosure, the upper heat source 710 may be a laser generator, and may supply heat to the substrate W by irradiating the substrate W with a laser. At this time, the size of the laser generator (more precisely, the laser irradiation region) is provided in a size corresponding to the size of the substrate W, so as to irradiate only the region of the substrate W with the laser. That is, by using the straightness of the laser, the thermal treatment area is capable of being limited and the thermal treatment effect on the surrounding area may be minimized.

A window 720 may be formed between the upper heat source 710 and the cooling plate 400b. The window 720 may serve to protect the upper heat source 710 by preventing etching by-products that occur as the process is performed from being deposited on the upper heat source 710. As an example, the window 720 may be a dielectric window. The window 720 is formed of a transparent member, so that a wavelength generated from the upper heat source 710 is capable of being transmitted through the window 720, thereby being capable of supplying heat to the substrate W. A modified metal film may be etched at an atomic layer level by simultaneously supplying heat from the heating unit 700 and supplying an inert gas from the gas supply unit 600.

The thermal treatment unit 200b of the present disclosure configured as described above is a Rapid Thermal Process (RTP) apparatus, and may be used when a rapid rise of temperature is required in a short time. In addition, the upper heat source 710 provided in the thermal treatment unit 200b is not limited to the laser generator, and may include other thermal treatment means capable of performing the rapid thermal process. For example, the upper heat source 710 may include a laser generator, a microwave generator, an infrared lamp, and so on. On the other hand, the upper heat source 710 may be positioned above and to a side of the cooling plate 400b instead of directly above the cooling plate 400b.

The lift driving part of the thermal treatment unit 200b may control the thermal treatment speed of the substrate W by adjusting a distance between the substrate W and the upper heat source 710. For example, when the thermal treatment is performed in a state in which the substrate W is moved upward by the lifting pins 408b (FIG. 5), the substrate W may be heated at a speed faster than a speed when the thermal treatment is performed in a state in which the substrate W is seated on the cooling plate 400b (FIG. 4). That is, the substrate W which is moved upward by the lift driving part and which is positioned closer to the upper heat source 710 may be heated at a relatively fast speed. The substrate W in which the thermal treatment is completed is moved downward by the lifting pins 408b and then is seated on the cooling plate 400b, so that a cooling treatment is capable of being performed. Particularly, when the upper heat source 710 is provided as a microwave generator, the lift driving part may increase the thermal treatment efficiency by adjusting a height of the substrate W.

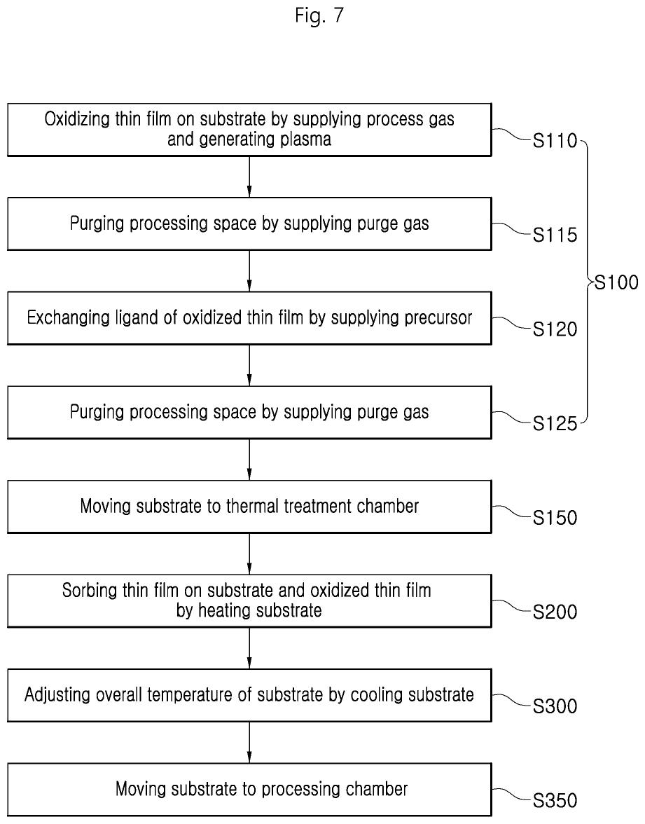

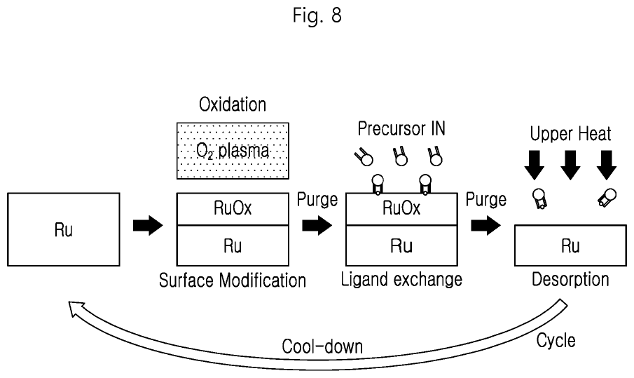

FIG. 7 is a flowchart illustrating a substrate treatment method according to an embodiment of the present disclosure. FIG. 8 is a view illustrating an example in which the substrate treatment method in FIG. 7 is applied. A substrate treatment method according to an embodiment of the present disclosure may be performed by the substrate treatment system of the present disclosure. Hereinafter, the substrate treatment method according to an embodiment of the present disclosure will be described with reference to FIG. 1 to FIG. 8.

The substrate treatment method according to an embodiment of the present disclosure includes a surface treatment process S100, a desorption process S200, and a temperature adjustment process S300. The surface treatment process S100, the desorption process S200, and the temperature adjustment process S300 are performed as one cycle, and a desired etching thickness may be obtained by repeating the cycle one or more times.

The surface treatment process S100 is a process for modifying a surface of a substrate. The surface treatment process S100 may be performed by the processing unit 200a, and may include an oxidation process S110 and a modification process S120.

The oxidation process S110 is a process in which the surface of the substrate is oxidized, and includes a process in which a process gas is supplied to the processing space of the processing unit 200a where the substrate W exists and then the process gas is converted into plasma. At this time, the process gas may include oxygen. The process gas radicalized and ionized by the plasma generation unit 500 may generate an oxide layer (an oxide film) by reacting with the thin film on the substrate W. At this time, a thickness of the generated oxide layer may be determined according to an oxidation condition.

The modification process S120 is a process of exchanging a ligand of the surface of the substrate, and includes a process of supplying a precursor to the processing space of the processing unit 200a by using the gas supply unit 600. The precursor supplied to the processing space is physically adsorbed to the oxide layer generated in the oxidation process S110. After then, the oxide film formed on the substrate W is not etched, but bond energy of the oxide film may be weakened through a ligand exchange reaction.

The cycle according to an embodiment of the present disclosure may further include a purge process. The purge process is a process in which a residual gas and process by-products in the processing space are removed by supplying a purge gas to the processing space. The purge process may be included in the surface treatment process S100.

A purge process S115 may be performed between the oxidation process S110 and the modification process S120. The purge process S115 is a process in which the purge gas is supplied to the processing space where the oxidation process S110 is completed, and may be performed by the gas supply unit 600 of the processing unit 200a. The purge gas may be supplied after the gas supply in the oxidation process S110 is stopped. The purge gas supplied to the processing space may be discharged outside the chamber 201 through the exhaust hole 202. According to the purge process S115, the residual gas and the reaction by-products which are supplied in the oxidation process S110 and which are remaining in the processing space may be removed. As an example, an inert gas such as argon (Ar), helium (He), and so on may be used as the purge gas.

When the modification process S120 is completed, another purge process S125 may be performed. The purge process S125 is a process in which the purge gas is supplied to the processing space where the modification process S120 is completed, and may be performed by the gas supply unit 600 of the processing unit 200a. The purge gas may be supplied after the gas supply in the modification process S120 is stopped. The purge gas supplied to the processing space may be discharged outside the chamber 201 through the exhaust hole 202. According to the purge process S125, the precursor and the reaction by-products which are supplied in the modification process S120 and which are remaining in the processing space may be removed. As an example, an inert gas such as argon (Ar), helium (He), and so on may be used as the purge gas.

When the surface treatment process S100 is completed, the desorption process S200 is performed. A first substrate transfer process S150 may be performed between the surface treatment process S100 and the desorption process S200. By the first substrate transfer process S150, the substrate W in which the surface treatment is completed in the processing unit 200a may be transferred to the thermal treatment unit 200b by the substrate transfer robot 340 of the substrate transfer module 30.

The desorption process S200 is a process in which a desorption reaction occurs on the surface of the surface-treated substrate. The desorption process S200 may be performed by the thermal treatment unit 200b.

The desorption process S200 includes a process of supplying an inert gas and heat simultaneously to the thermal treatment space of the thermal treatment unit 200b where the substrate W in which the surface is performed exists. Heat is supplied to the substrate W by using the heating unit 700 that includes the upper heat source 710 and, at the same time, the inert gas is supplied to the thermal treatment space by using the gas supply unit 600, so that the oxide film in which the bond energy is weakened may be desorbed at an atomic layer level. According to an embodiment of the present disclosure, by using a laser generator, the substrate may be irradiated with a laser, and argon (Ar), helium (He), and so on may be used as an inert gas. The oxide film desorbed by the desorption process S200 may be discharged to the exhaust hole 202 along with the inert gas supplied to the thermal treatment space.

Selectively, the desorption process S200 may further include a process of adjusting the height of the substrate W with respect to the cooling plate 400b. The substrate W may be lifted by the lift driving part. Furthermore, as the substrate W is moved upward, the distance between the substrate W and the upper heat source 710 is shortened, so that the heating speed of the substrate W may be increased. For example, when the thermal treatment is performed in a state in which the substrate W is moved upward by the lifting pins 408b (FIG. 5), the substrate W may be heated at a speed faster than a speed when the thermal treatment is performed in a state in which the substrate W is seated on the cooling plate 400b (FIG. 4). That is, the substrate W which is moved upward by the lift driving part and which is positioned closer to the upper heat source 710 may be heated at a relatively fast speed. The substrate W in which the thermal treatment is completed is moved downward by the lifting pins 408b and then is seated on the cooling plate 400b, and then the substrate W may be cooled by the temperature adjustment process S300. Particularly, when the upper heat source 710 is provided as a microwave generator, the thermal treatment efficiency is capable of being increased by adjusting the height of the substrate W.

The temperature adjustment process S300 is a process for maintaining the temperature of the substrate W to a set temperature range, and includes a process in which the cooling plate 400b of the thermal treatment unit 200b cools the substrate W. The temperature adjustment process S300 may be performed by supplying a cooling fluid to the cooling member 406b. The cooling fluid supplied to the cooling member 406b may cool the substrate W by circulating along the cooling line while the temperature adjustment process S300 is performed. When the temperature adjustment process S300 is not performed, the cooling fluid supply to the cooling member 406b is stopped, and the cooling fluid that exists inside the cooling member 406b may be recovered.

The temperature adjustment process S300 may be performed immediately after the desorption process S200, so that the substrate W heated in the desorption process S200 may be cooled. Particularly, since the temperature adjustment process S300 is performed by the cooling plate 400b that cools the substrate W while the cooling plate 400b is in contact with the substrate W, the cooling speed and the cooling efficiency of the substrate W may be significantly increased. As the cooling process with improved efficiency is performed in the temperature adjustment process S300, a phenomenon in which the temperature of the substrate W is increased may be suppressed even after the cycle is repeated, so that the temperature of the substrate W may be prevented from deviating from the set temperature range. In addition, a change in the physical properties of the surface of the thin film and a decrease in the etching rate caused by an increase in the temperature of the substrate W may be prevented. For example, when the etching target is a ruthenium thin film, the temperature adjustment process S300 may maintain a temperature of the substrate W at a temperature less than 100 degrees Celsius by using the cooling process.

Selectively, the temperature adjustment process S300 is performed simultaneously with the desorption process S200, so that the substrate W may be prevented from overheating during the desorption process S200. The temperature adjustment process S300 that is performed simultaneously with the desorption process S200 may prevent the substrate W from being overheated by the rapid thermal treatment during the desorption process S200, and may cool the substrate W after the desorption process S200 is completed, in which the substrate W is heated during the desorption process S200. In addition, according to the temperature adjustment process S300 that starts at the same time as the desorption process S200 starts, thermal energy by the heating unit 700 is minimized to reach the lower surface of the substrate W during the desorption process S200, so that the thermal treatment may be concentrated on the surface of the substrate W and damage to the lower portion of the substrate W may be prevented.

When the temperature adjustment process S300 is completed, a second substrate transfer process S350 may be performed. The second substrate transfer process S350 may be performed by the substrate transfer robot 340 of the substrate transfer module 30. When a subsequent cycle exists for the substrate W performed up to the temperature adjustment process S300, the second substrate transfer process S350 is performed such that the substrate W in which the temperature adjustment process S300 is completed is transferred to the processing unit 200a from the thermal treatment unit 200b. On the other hand, when a subsequent cycle does not exist, the second substrate transfer process S350 may be performed such that the substrate W in which the temperature adjustment process S300 is completed is transferred to the load lock chamber 15 from the thermal treatment unit 200b. Alternatively, the second substrate transfer process S350 may a process of transferring the substrate W to another processing unit 200 other than the processing unit 200a.

The cycle described above is performed again on the substrate W transferred to the processing unit 200a, and the substrate W transferred to the load lock chamber 15 is carried out of the substrate treatment system, and another treatment process may be performed on the substrate W transferred to another processing unit 200 other than the processing unit 200a.

FIG. 8 is a view illustrating a process of etching a substrate W including a ruthenium (Ru) thin film. Referring to FIG. 8 from a left side to a right side, a ruthenium oxide (RuOx) film is formed on a surface of the ruthenium thin film by the oxidation process S100 in which plasma including oxygen is formed (surface modification). After then, a ligand of the surface is exchanged (ligand exchange) by the modification process S120 in which injecting of a precursor is performed, and then the modified surface is etched by being desorbed (desorption) by heat applied from above the surface in the desorption process S200. The substrate heated in the desorption process S200 may be cooled by the temperature adjustment process S300 (cool-down), and one cycle from the oxidation process S110 to the temperature adjustment process S300 may be repeated until the etching is performed to the target thickness. According to one cycle, one layer of an atomic layer is etched. In the ruthenium thin film, when the temperature of the substrate W is overheated to a temperature of equal to or more than 100 degrees Celsius, additional etching (i.e., overetching) occurs during the surface modification process, and ruthenium tetroxide (RuO₄) that is volatile may be formed other than ruthenium dioxide (RuO) that is non-volatile. Since ruthenium tetroxide (RuO₄) in a gaseous state is a toxic gas and may cause environmental safety problems, maintaining the temperature of the substrate in the ruthenium etching process is significantly important. Therefore, when the present disclosure in which the temperature of the substrate is capable of being maintained in a constant temperature range is applied to the etching of ruthenium, the generation of ruthenium tetroxide that is toxic gas may be prevented.

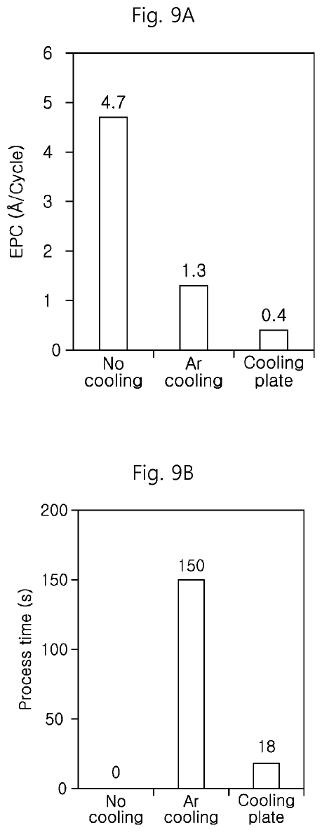

FIGS. 9A and 9B are views illustrating experimental data comparing an example of cooling a substrate including a ruthenium thin film in a conventional manner with an example of applying the present disclosure to a substrate including a substrate including a ruthenium thin film. FIG. 9A illustrates each Etch rate Per Cycle (EPC) according to cooling methods, and FIG. 9B illustrates each substrate cooling time according to the cooling methods.

First, referring to FIG. 9A, it can be seen that the etching rate per cycle decreases in the following order: when the substrate is not cooled (No cooling), when the substrate is cooled by an air-cooling method (Ar cooling), and when the substrate is cooled by a contact method (Cooling plate).

In addition, referring to FIG. 9B, it can be seen that the time required to cool the substrate is significantly reduced when the substrate is cooled by using the contact method (Cooling plate) compared to when the substrate is cooled by using the air-cooling method (Ar cooling).

Through this, it may be confirmed that cooling the substrate by the contact method is significantly advantageous in terms of cooling efficiency, and that additional etching due to overheating of the substrate may be suppressed by preventing an increase in the substrate temperature.

As described above, in the atomic layer etching process in which the substrate cooling method using the contact method is applied, the cooling speed and the cooling efficiency of the substrate W are increased, so that the temperature increase phenomenon of the entire substrate W by the repetitive process may be prevented, and the temperature increase phenomenon of the treatment space may be prevented. Accordingly, even in the repetitive process that is characteristic of the atomic layer level treatment process, the substrate may be treated under the same process condition. That is, process stability and process reproducibility may be secured.

In addition, according to the present disclosure, since overheating of the substrate W is prevented, damage to the substrate such as deformation of the substrate, damage to the pattern, damage to the surface, and so on due to overheating of the substrate W may be prevented. In addition, changes in the physical properties of the thin film that may occur as the temperature of the substrate W exceeds an allowable range may be minimized, and the generation of the harmful gas (toxic gas) may be minimized.

In addition, the process time may be reduced by high-speed heating and high-speed cooling, and the substrate W may be prevented from overheating during the thermal treatment process by cooling the lower surface of the substrate W even while the heating process is performed.

In addition, since each temperature range of the surface treatment process and the desorption process is not limited because the temperature range of the surface treatment process and the temperature range of the desorption process do not affect each other due to a dual chamber configuration, the process temperature range may be expanded compared to the process performed in a single chamber, and an etch selectivity may be further increased, so that yield of a product may be increased. Etching quantity control may also be more easily performed.

Meanwhile, the substrate treatment method according to the present disclosure is sufficiently applicable to a substrate treatment apparatus in which a processing unit and a thermal treatment unit are configured as a single chamber. In addition, although the atomic layer etching process is described in the present specification as an example, the present disclosure may also be applied to an atomic layer deposition process.

The present exemplary embodiment and the accompanying drawings in this specification only clearly show a part of the technical idea included in the present disclosure, and it will be apparent that all modifications and specific exemplary embodiments that can be easily inferred by those skilled in the art within the scope of the technical spirit contained in the specification and drawings of the present disclosure are included in the scope of the present disclosure.

Therefore, the spirit of the present disclosure should not be limited to the described exemplary embodiments, and all things equal or equivalent to the claims as well as the claims to be described later fall within the scope of the concept of the present disclosure.

What is claimed is:

1. A substrate treatment method etching a substrate at an atomic layer level by using a processing unit and a thermal treatment unit, the substrate treatment method comprising:
a surface treatment process in which a surface of the substrate is modified in the processing unit;
a desorption process in which the substrate that is surface-treated in the processing unit is heated by an upper heat source in the thermal treatment unit, thereby generating a desorption reaction on the surface of the substrate that is surface-treated; and
a temperature adjustment process in which the substrate is cooled by a cooling plate in the thermal treatment unit, thereby maintaining a temperature of the substrate at a set temperature range.

2. The substrate treatment method of claim 1, wherein the surface treatment process, the desorption process, and the temperature adjustment process constitute one cycle and are repeated one or more times.

3. The substrate treatment method of claim 2, wherein the cycle comprises:
a first substrate transfer process performed between the surface treatment process and the desorption process; and
a second substrate transfer process performed after the temperature adjustment process, and
the first substrate transfer process is performed such that the substrate is transferred to the thermal treatment unit from the processing unit, and the second substrate transfer process is performed such that the substrate is transferred to the processing unit from the thermal treatment unit when a subsequent cycle exists.

4. The substrate treatment method of claim 3, wherein the surface treatment process comprises:
an oxidation process in which a process gas including oxygen is supplied to a processing space of the processing unit and then the process gas is converted into plasma, thereby oxidizing the surface of the substrate; and
a modification process in which a ligand of the surface that is oxidized by the oxidation process is exchanged by supplying a precursor to the processing space.

5. The substrate treatment method of claim 4, wherein the surface treatment process further comprises a purge process purging the processing space of the processing unit, and the purge process is performed between the oxidation process and the modification process and is performed after the modification process.

6. The substrate treatment method of claim 4, wherein the substrate comprises a ruthenium (Ru) thin film, and the set temperature range is a temperature range in which RuO₄ is not generated on the ruthenium thin film during the oxidation process.

7. The substrate treatment method of claim 2, wherein the temperature adjustment process starts immediately after the desorption process or starts simultaneously with the desorption process.

8. The substrate treatment method of claim 7, wherein the desorption process is performed in a state in which the substrate is seated on the cooling plate, or is performed in a state in which the substrate is moved upward from the cooling plate.

9. A substrate treatment system comprising:
a processing unit configured to treat a surface of a substrate by using plasma; and
a thermal treatment unit configured to etch the substrate at an atomic layer level by heating the substrate that is surface-treated in the processing unit,
wherein the thermal treatment unit comprises:
a chamber having a thermal treatment space therein;
a heating unit comprising an upper heat source and being configured to heat the substrate; and
a cooling plate configured to cool the substrate in a contact method in the thermal treatment space, and
a cooling flow path in which a cooling fluid flows is provided inside the cooling plate.

10. The substrate treatment system of claim 9, wherein the cooling plate further comprises a lift driving part configured to move the substrate upward or downward.

11. The substrate treatment system of claim 10, wherein the lift driving part is configured to move the substrate upward or downward by using a plurality of lifting pins that supports a lower surface of the substrate, and the plurality of lifting pins is accommodated in a plurality of pin holes that penetrates the cooling plate in up and down directions.

12. The substrate treatment system of claim 9, wherein the upper heat source comprises any one of a laser generator, a microwave generator, and an infrared lamp.

13. The substrate treatment system of claim 9, wherein the processing unit comprises:
a chamber having a processing space therein;
a supporting unit provided at a lower portion of the processing space and being configured to support the substrate;
a plasma generation unit for generating plasma in the processing space; and
a gas supply unit configured to supply a process gas to the processing space.

14. The substrate treatment system of claim 9, wherein the substrate comprises a ruthenium (Ru) thin film.

15. A substrate treatment method etching a substrate comprising a ruthenium (Ru) thin film at an atomic layer level by using a processing unit and a thermal treatment unit, the substrate treatment method comprising:
a surface treatment process in which a surface of the Ru thin film is modified in the processing unit;
a first substrate transfer process in which the substrate that is surface-treated in the surface treatment process is transferred to the thermal treatment unit from the processing unit;
a desorption process in which the substrate that is transferred to the thermal treatment unit and surface-treated is heated by an upper heat source, thereby generating a desorption reaction on the surface of the substrate that is surface-treated; and
a temperature adjustment process in which the substrate is cooled by a cooling plate in the thermal treatment unit, thereby maintaining a temperature of the substrate at a set temperature range,
wherein the surface treatment process, the desorption process, and the temperature adjustment process constitute one cycle and are repeated one or more times, and the substrate treatment method comprises a second substrate transfer process of transferring the substrate in which the temperature adjustment process is completed to the processing unit from the thermal treatment unit when a subsequent cycle exists.

16. The substrate treatment method of claim 15, wherein the surface treatment process comprises:
an oxidation process in which a process gas comprising oxygen is supplied to a processing space of the processing unit and then the process gas is converted into plasma, thereby oxidizing the surface of the Ru thin film; and
a modification process in which a ligand of the surface of the Ru thin film that is oxidized by the oxidation process is exchanged by supplying a precursor to the processing space.

17. The substrate treatment method of claim 16, wherein the temperature adjustment process prevents a generation of Ru₀₄ in the oxidation process due to repetition of the cycle from occurring.

18. The substrate treatment method of claim 16, wherein the surface treatment process further comprises a purge process purging the processing space of the processing unit, and the purge process is performed between the oxidation process and the modification process and is performed after the modification process.

19. The substrate treatment method of claim 16, wherein the temperature adjustment process starts immediately after the desorption process or starts simultaneously with the desorption process.

20. The substrate treatment method of claim 19, wherein the desorption process is performed in a state in which the substrate is seated on the cooling plate, or is performed in a state in which the substrate is moved upward from the cooling plate.
